(19) United States
(12) Patent Application Publication
(10) Pub. No.: US 2023/0359029 A1
(43) Pub. Date: Nov. 9, 2023

(54) Tunable Florescent Quantum Dot System for Eye Tracking with Virtual Reality and Augmented Reality Applications

(71) Applicant: META PLATFORMS, INC., Menlo Park, CA (US)

(72) Inventors: Alfredo Bismuto, Bellevue, WA (US); Francis Lawrence Leard, Sudbury, MA (US); Sascha Hallstein, Saratoga, CA (US)

(21) Appl. No.: 17/738,546

(22) Filed: May 6, 2022

(51) Int. Cl. G02B 27/01; G06F 3/01; G02B 27/00; H01L 31/0352; H01L 31/0216

(52) U.S. Cl. CPC G02B 27/0172; G06F 3/013; G02B 27/0093; H01L 31/035218; H01L 31/0216; G02B 2027/0187

(57) ABSTRACT

A tunable fluorescent quantum dot may be utilized for illumination of artificial reality displays or waveguides. The tunable quantum dot may include a core fluorescence quantum dot and multiple coatings that may activate based on different wavelengths of one or more activation energies.

### TECHNOLOGICAL FIELD

Exemplary embodiments of this disclosure relate generally to methods, apparatuses, and computer program products for providing tunable florescent quantum dot systems for eye tracking or other systems with virtual reality or augmented reality applications.

### BACKGROUND

Artificial reality is a form of reality that has been adjusted in some manner before presentation to a user, which may include, for example, a virtual reality, an augmented reality, a mixed reality, a hybrid reality, or some combination or derivative thereof. Artificial reality content may include completely computer-generated content or computer-generated content combined with captured (e.g., real-world) content. The artificial reality content may include video, audio, haptic feedback, or some combination thereof, any of which may be presented in a single channel or in multiple channels (such as stereo video that produces a three-dimensional (3D) effect to the viewer). Additionally, in some instances, artificial reality may also be associated with applications, products, accessories, services, or some combination thereof, that are used to, for example, create content in an artificial reality or are otherwise used in (e.g., to perform activities in) an artificial reality. Head-mounted displays (HMDs) including one or more near-eye displays may often be used to present visual content to a user for use in artificial reality applications.

### BRIEF SUMMARY

Methods and systems for creating a tunable fluorescence quantum dot system that may be used in systems, such as artificial reality systems are disclosed. In an example, a tunable fluorescent quantum dot includes a core, wherein the core comprises a fluorescent quantum dot (f-dot) of a first size, the core comprises a first material that is activated by a first activation energy; and a coating layer, wherein the coating layer substantially encompasses the core. The coating layer may include a second material that is activated by a second activation energy. The first activation energy may be different from the second activation energy.

Additional advantages will be set forth in part in the description which follows or may be learned by practice. The advantages will be realized and attained by means of the elements and combinations particularly pointed out in the appended claims. It is to be understood that both the foregoing general description and the following detailed description are exemplary and explanatory only and are not restrictive, as claimed.

The summary, as well as the following detailed description, is further understood when read in conjunction with the appended drawings. For the purpose of illustrating the disclosed subject matter, there are shown in the drawings exemplary embodiments of the disclosed subject matter; however, the disclosed subject matter is not limited to the specific methods, compositions, and devices disclosed.

### BRIEF DESCRIPTION OF THE DRAWINGS

A more detailed understanding may be had from the following description, given by way of example in conjunction with the accompanying drawings wherein:

FIG. 1 is an exemplary head-mounted display.

FIG. 2A is a diagram illustrating a photonics integrated circuit layer associated with a head-mounted display.

FIG. 2B is a diagram illustrating cross section detail of a termination node associated with a waveguide.

FIG. 2C is a diagram illustrating cross section details of illumination sources emitting illumination associated with a wavelength.

FIG. 3A is an exemplary fluorescent quantum dot.

FIG. 3B is an exemplary spectral emission graph composed of irradiance response versus spectra distribution.

FIG. 3C is an exemplary tunable fluorescent quantum dot.

FIG. 3D is an exemplary spectral emission graph composed of irradiance response versus spectra distribution that includes a spectral shift.

FIG. 4 is a diagram of an exemplary process for tuning an f-dot.

FIG. 5 is an exemplary block diagram of a device.

The figures, which are not necessarily to scale, depict various examples for purposes of illustration only. One skilled in the art will readily recognize from the following discussion that alternative examples of the structures and methods illustrated herein may be employed without departing from the principles described herein.

### DETAILED DESCRIPTION

The subject matter will now be described more fully hereinafter with reference to the accompanying drawings, in which some, but not all examples of the subject matter are shown. Indeed, various examples are in many different forms and should not be construed as limited to the examples set forth herein. Like reference numerals refer to like elements throughout.

It is to be understood that the methods and systems described herein are not limited to specific methods, specific components, or to particular implementations. It is also to be understood that the terminology used herein is for the purpose of describing particular examples only and is not intended to be limiting.

HMD's including one or more near-eye displays may often be used to present visual content to a user for use in artificial reality applications. One type of near-eye display may include an enclosure that houses components of the display or is configured to rest on the face of a user, such as for example a frame. The near-eye display may include a waveguide that directs light from a projector to a location in front of the user's eyes. With conventional photonics integrated circuit (PIC) systems in which the eye illumination and the camera spectral bandwidth are the same, there is a tendency that stray light leakage from the waveguides may contaminate the glint image seen from the eye, thus reducing the contrast ratio of the eye image.

The disclosed subject matter allows for tuning to create a color emission display using a remote tunable fluorescent quantum dot (t-f-dot or ^{t}dot_{f}) as an illumination for other uses in an artificial reality system or permitting eye tracking (ET) functionality. Activation (e.g., excitation) may be performed using a series of control or excitation PICs and fed by one or more sources that allows for a lightweight and low power system for ET or other functionality. A Fabry Perot thin film cavity (FPTFC) may be applied to a f-dot using atomic layer deposition (ALD) methods with a monolayer being applied to f-dot, such as for hydroxyl protection. The disclosed tunable f-dot system may allow for a reduction in space, cost, or weight for a HMD, as well as potentially reducing interference with the display path that may interrupt the users experience.

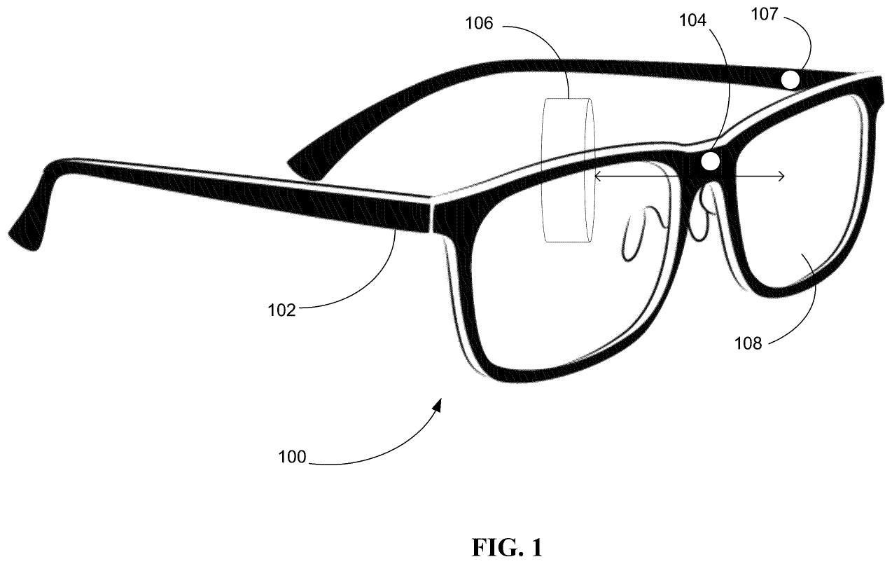

FIG. 1 illustrates an example head-mounted display (HMD) 100 associated with artificial reality content. HMD 100 may include enclosure 102 (e.g., an eyeglass frame), sensor 104, sensor 107, or display 108 (e.g., lenses). Display 108 may include a waveguide and may be configured to direct images to surface 106 (e.g., user's eye or another structure). In some examples, head-mounted display 100 may be implemented in the form of augmented-reality glasses. Accordingly, display 108 may be at least partially transparent to visible light to allow the user to view a real-world environment through display 108.

Tracking of surface 106 may be significant for graphics rendering and user peripheral input. HMD 100 design may include sensor 104 (e.g., a front facing camera away from a primary user) and sensor 107 (e.g., a rear facing camera towards a primary user). Sensor 104 or sensor 107 may track movement or gaze of a user's eyes. HMD 100 may include an eye tracking system to track the vergence movement of a user's eyes. Sensor 104 may capture images or videos of an area, while sensor 107 may capture video or images associated with surface 106 (e.g., a user's eyes or other areas of the face). Sensor 107 may be used detect the reflection off of surface 106 (e.g., glint of a user's eye). Sensor 104 or sensor 107 may be located on frame 102 in different positions. Sensor 104 or sensor 107 may have multiple purposes and may encompass the entire the width of a section of frame 102, may be just on one side of frame 102 (e.g., nearest to the user's eye), or may be located on display 108.

Herein, glint may refer to light reflected at an angle from a target surface (e.g., one or more eyes). A glint signal is any point-like response from the eye from an energy input. Examples of energy inputs may be any form of time, space, frequency, phase, or polarized modulated light or sound. Additionally, glint signals may result from a broad area of illumination where the nature of the field of view from the receiving eye tracking technology may allow detection of point like response from the surface pixels or the volume voxels of the eye (e.g., combination of the detection system with desired artifacts on the surfaces/layers of the eye or within its volume). This combination of illumination and detection field of views coupled with desired artifacts on the layers/volumes may result in point like responses from the eye (e.g., glints).

An f-dot may be more generally referred to as a fluorophore. Herein, a fluorophore may be a material that takes in photons at a first wavelength (also referred to herein as wavelength λ1) and emits photons at a second wavelength (also referred to herein as wavelength λ2) with the conversion (e.g., from wavelength λ1 to wavelength λ2) occurring due to quantum energy level shifts with the material of the fluorophore's physical or chemical make-up. In some examples, a fluorophore may be a phosphor, a fluorescent nanocrystal, a fluorescent quantum dot (e.g., f-dot), or other suitable fluorophores. The material of a fluorophore may be composed of organic or inorganic compounds.

Placing a remote fluorophore such as a stokes phosphor (e.g., a remote phosphor), or an anti-stokes phosphor, in the form of a fluorophore (e.g., quantum dot (QD), nanocrystal, etc.) at a terminus of waveguides and at a focus of lenses of HMD 100, the illumination wavelengths may be moved to a waveband outside of the vision of humans and perceptible by a camera such as, for example, a near infrared (NIR) camera, which may be utilized for glint detection.

A wavelength in the blue to near infrared band may be utilized as long as that band is out of the spectral range of camera 107. In this regard, blue light wavelengths may be utilized. In some examples, 780 nanometer (nm) or 840 nm or the like illumination sources may be utilized with fluorophores, such as quantum dots to shift a wavelength to 980 nm for glint emission.

In some examples, anti-stokes fluorophores (e.g., anti-Stokes phosphors) may allow an illumination wavelength to be shifted to a wavelength greater than or equal to 1250 nm (e.g., an eye safe region) while still allowing for the glint emission to be in the 980 nm band that camera 107 may perceive.

A stokes fluorophore (also referred to herein as stokes phosphor) may absorb radiation (e.g., in the form of photons) at wavelength λ1 and may emit a lower energy (e.g., longer wavelength) at wavelength λ2. This may be enacted by the material of the stokes fluorophore by way of a quantum mechanical exchange due to an incoming photon (e.g., an excitation source) causing a lower bound electron to rise to a higher energy state which may have a fast decay time to a lower energy state that may not be a ground state and as such may emit a lower energy (e.g., longer wavelength-wavelength λ2).

An anti-stokes fluorophore may be similar to a stokes fluorophore in energy states but the anti-stokes fluorophore may include a series of sub-bands or defect bands going from a lower energy state to a higher energy state. Each of the sub-bands may have a long decay time such that energy within an eye tracking system (e.g., HDM 100 having an eye tracking camera 107) may build up by absorbing photons of lower energy at a wavelength such as, for example, a wavelength λ3. In an instance in which electrons attain enough energy to pass into the higher energy state, which may also have a short decay time with a direct path to an energy state lower than where the electrons first started, this electron state may emit a photon at a shorter wavelength such as wavelength λ2. In some examples, wavelength λ2 may be a desired wavelength for eye tracking systems.

As described in more detail herein, by utilizing stokes fluorophores or anti-stokes fluorophores, a source illumination such as light having a wavelength λ1 or wavelength λ3 may not be detected by camera 107 because this source illumination may be filtered out by optical wavelength filters in front of a photodetection surface associated with camera 107 or may be above an absorption spectral band or below the absorption spectral band of detector elements associated with the camera 107. As such, the signal to noise ratio or the contrast ratio of camera 107 may be improved due to a lack of ambient noise being present in eye tracking systems that emit or detect source illumination having wavelength λ1 or wavelength λ3.

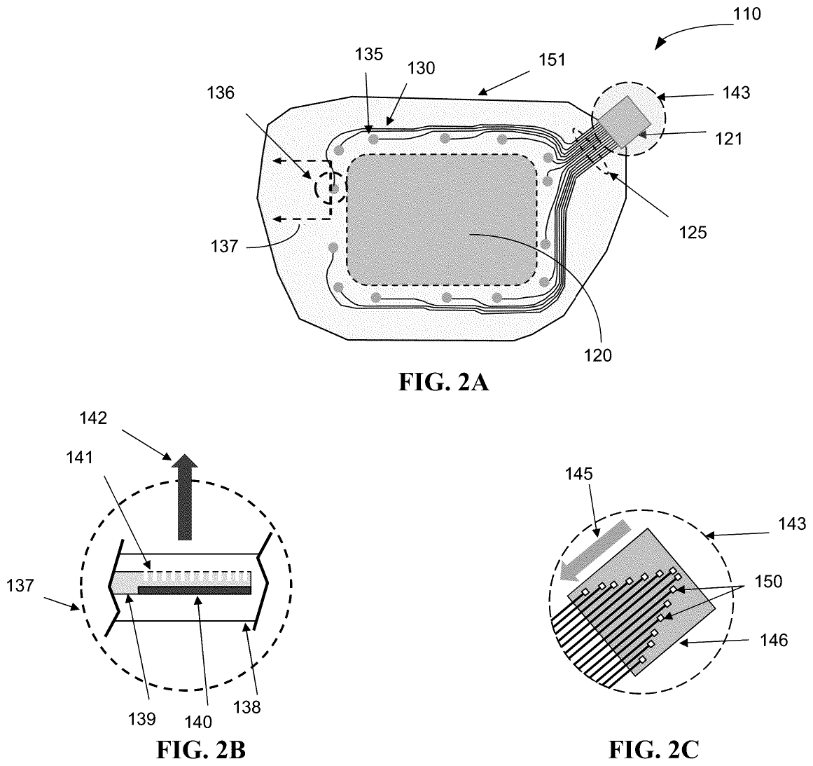

FIG. 2A illustrates an exemplary diagram of a photonics integrated circuit (PIC) layer of a display 108 associated with HMD 100. PIC layer 110 may include a remote fluorophore illumination system for eye tracking applications. The PIC layer 110 may include a PIC layer 151 that incorporates remote fluorophores. PIC layer 110 may include or connect with one or more illumination sources (e.g., a light projector—not shown in FIG. 2A) which may illuminate light (e.g., at wavelength λ1). For instance, PIC layer 110 may also include a source illumination carrier 121 including one or more illumination sources. Further, PIC layer 110 may include a keep-out region 120 which may be dedicated to artificial reality display presentation. PIC layer 110 may include an exemplary array of PIC waveguides 125. The array of PIC waveguides 125 may be configured to transport source illumination (e.g., at wavelength λ1) from the source illumination carrier 121 to an emission port(s) (e.g., termination node 135 or termination node 136). As an example, PIC waveguide 130 may be one of the PIC waveguides 125 utilized to transport source illumination (e.g., at wavelength λ1). Termination node 135 may be a termination node of a PIC waveguide carrying illumination (e.g., at wavelength λ1). Termination node 136 may be another termination node of another PIC waveguide carrying illumination (e.g., at wavelength λ1). The cross section 137 may be a cut through view of termination node 136 which is shown more fully in cross section 137 of FIG. 2B.

FIG. 2B illustrates exemplary cross section detail of a termination node associated with PIC waveguide. Cross section 137 may be associated with termination node 136 of PIC waveguide 130. Cross section 137 associated with termination node 136 illustrates cross section 138 details of PIC layer 151 that includes remote fluorophores. Cross section 139 details the cross section of PIC waveguide 130 configured to transport an illumination source (e.g., at wavelength λ1). A remote fluorophore 140 is shown in FIG. 2B and is located along the cross section 139 at the termination node 136. The remote fluorophore 140 may absorb illumination (e.g., light) at a wavelength λ1 and may emit illumination at a wavelength λ2.

Output coupler 141 of FIG. 2B may be configured to react to light having wavelength λ2 and direct it out of the PIC waveguide 130 normal to (e.g., approximately perpendicular to) the surface of PIC layer 151 at termination node 136. Output coupler 141 may be a surface relief grating, a volume hologram, a polarization volume hologram, a diffractive optical element, a meta-antenna, an excitonic or plasmonic circuit, or other resonance-based structure that may react to wavelength λ2 to extract light associated with wavelength λ2 from 130 and directing the associated light normal to PIC layer 151 along a path of termination node emission 142. The output coupler 141 may modify the spatial or angular profile of termination node emission 142 based on the design of output coupler 141.

In the example of FIG. 2B, output coupler 141 may facilitate or otherwise cause termination node emission 142 associated with termination node 136 pertaining to PIC waveguide 130. Output coupler 141 may shape the termination node emission 142 and the termination node emission 142 may emit light associated with wavelength λ2 from PIC waveguide 130 and may emit the light towards an eye(s) of a user to be utilized as an eye tracking beam.

FIG. 2C illustrates exemplary cross section 143, which details of components for emitting light associated with a wavelength. Cross section 143 may illustrate details associated with illumination sources 150 configured to emit light associated with a wavelength such as wavelength λ1 or other suitable wavelengths. The light may be emitted by the illumination sources 150 according to a direction 145 associated with wavelength λ1 within each of the PIC waveguides of the array of PIC waveguides 125. The source illumination carrier 146 may illustrate an expanded view of the source illumination carrier 121, in FIG. 2A, which may include illumination sources 150 each emitting light associated with wavelength λ1 or other suitable wavelengths. In this regard, illumination sources 150 may be sources of emitting light having a wavelength λ1. In some examples, the illumination sources 150 may be light emitting diodes (LEDs) or lasers. The lasers may be vertical cavity surface emitting lasers (VCSELs), stripe guide lasers, or stabilized grating lasers (e.g., wavelength or polarization).

In some examples, PIC layer 110 may be associated with HMD 100, which may include an eye tracking system (e.g., track the vergence movement of a user's eyes wearing). In an example, camera 107 may track movement or gaze of a user's eyes. In this regard, the illumination sources 150 (e.g., LEDs or lasers) may emit light to be directed towards an eye(s) in which the light may be utilized as an eye tracking beam. In an example, a wavelength associated with wavelength λ1 may be 460 nm. Other suitable examples of wavelength λ1 (e.g., 780 nm, 840 nm) may be possible. In some examples, one or more of the illumination sources 150 may emit in a blue/ultraviolet visible spectrum or in a near infrared visible spectrum. In an instance in which anti-Stokes phosphors are utilized, the anti-Stokes phosphors may allow an illumination wavelength to be shifted to any wavelength (e.g., wavelength λ3) greater than 1250 nm (e.g., an eye safe region) while still allowing for the illumination wavelength emission for detecting a glint image to be in the 980 nm band (e.g., wavelength λ2) that a camera may view without any potential eye safety issues. A remote fluorophore (e.g., remote fluorophore 140) located at PIC waveguide 130 may convert wavelength λ1 to a desired wavelength that may be beneficial for eye tracking, as described herein.

For example, the illumination sources 150, of the source illumination carrier 146, may be configured to facilitate emission of light into PIC waveguide 130. The light (e.g., an illumination source having wavelength λ1) may travel/propagate to a termination node (e.g., termination node 136 or termination node 135) of PIC waveguide 130. For example, the light may travel to termination node 136. As shown in the cross section 137, of FIG. 2B, detailing the termination node 136, in which the light may travel along the PIC waveguide 130 (see e.g., cross section 139) and to remote fluorophore 140 of PIC waveguide 130 which may absorb the light having wavelength λ1 (e.g., 460 nm) and emit light having wavelength λ2. In this example, a wavelength associated with wavelength λ2 may be 980 nm. In this regard, remote fluorophore 140 may shift the light from wavelength λ1 (e.g., 460 nm) to a wavelength λ2 (e.g., 980 nm) which may be a wavelength region safe for an eye(s) of a user and may be a wavelength region capable of detection by camera 107. As such, even in an instance in which there may be stray light leakage from a PIC waveguide (e.g., PIC waveguide 130), camera 107 may not perceive (or otherwise ignore) the leaked light because the leaked light may not be in the visible spectra that camera 107 (or another device) is configured to detect or process.

Remote fluorophore 140 (e.g., a stokes fluorophore may absorb radiation (e.g., in the form of photons) at a wavelength λ1 (e.g., 460 nm) and remote fluorophore 140 may emit a lower energy (e.g., longer wavelength) at a wavelength λ2 (e.g., 980 nm). This may be enacted in the material of the remote fluorophore (e.g., a stokes fluorophore) by way of a quantum mechanical exchange due to an incoming photon (e.g., an excitation source) causing a lower bound electron to rise to a higher energy state which may have a fast decay time to a lower energy state that may not be a ground state and as such may emit a lower energy (e.g., longer wavelength). This wavelength selectivity on the excitation wavelength (460 nm, etc.) may be attained by structuring the quantum dot (e.g., resonant coatings), as disclosed in more detail herein, or adding compounds that negate the effects of undesired wavelengths (defects and traps with the electronic structure to negate undesired wavelengths). The size of the quantum dot may dictate emission wavelengths to that of only the desired emission wavelength (e.g., 980 nm).

In response to remote fluorophore 140 shifting the light from wavelength λ1 (e.g., 460 nm) to wavelength λ2 (e.g., 940 nm), output coupler 141 may react to the light having wavelength λ2 and may direct the light out of PIC waveguide 130, along termination node emission 42 path normal to a surface of the PIC layer 151 at a termination node (e.g., termination node 136). The termination node emission 142 may shape the light having wavelength λ2 from output coupler 141 and may emit the light having wavelength λ2 towards an eye(s) of a user (e.g., a user wearing HMD 100) as an eye tracking beam. In this example, the termination node emission 142 may be associated with light having wavelength λ2 (e.g., 960 nm), whereas the light from one or more illumination sources 150 may be associated with wavelength λ1 (e.g., 460 nm). For purposes of illustration, camera 107 associated with HMD 100 may be only capable of detecting light associated with wavelength λ2 (e.g., an eye safe wavelength). In other words, the light associated with wavelength λ1 emitted by one or more of the illumination sources 150 may be invisible (e.g., undetectable) to camera 107. Camera 107 may be unable to detect any light having a wavelength band that is outside of the spectral range of camera 107. As such, even in an instance in which stray light having wavelength λ1 may leak from PIC waveguide 130, the stray light may be undetectable by camera 107 because it may be outside of the spectral range of camera 107. Since the stray light may be outside of the spectral range of camera 107, the stray light may not degrade a signal to noise ratio (SNR), or a contrast ratio associated with camera 107. Furthermore, as described above, the light having wavelength λ2 that is directed, by the termination node emission 142, to an eye(s) of a user as an eye tracking beam may be safe for eyes.

In some alternatives, remote fluorophore 140 may be a remote phosphor such as an anti-stokes phosphor which may allow light emitted from one or more illumination sources 150 at wavelength λ3 or greater (e.g., 1250 nm or greater) to be shifted by remote fluorophore 140, in PIC waveguide 130 at a termination node, to be in wavelength λ1 band (e.g., 980 nm) that camera 107 may be able to detect. Wavelength λ3 may be in an eye safe region. Remote fluorophore 140 as an anti-stokes phosphor may be in PIC waveguide 130 at a termination node (e.g., termination node 136 or termination node 135) in a same manner as described herein regarding a stokes phosphor as remote fluorophore 140.

The anti-stokes phosphor may be similar to the stokes phosphor in energy states, but the anti-stokes phosphor may include a series of sub-bands or defect bands going from a lower energy state to a higher energy state. Each of the sub-bands may have a long decay time such that energy within an eye tracking system (e.g., HMD 100) may build up by absorbing photons of lower energy at wavelength λ3. In an instance in which electrons attain enough energy to pass into the higher energy state, which also may have a short decay time with a direct path to an energy state lower than where the electrons first started, that electron state may emit a photon at wavelength λ2 (e.g., a shorter wavelength) and wavelength λ2 may be a desired wavelength for eye tracking associated with camera 107. The illumination (e.g., light) emitted from the source illuminators having wavelength λ1 and wavelength λ3 may not be detectable by camera 107 since these wavelengths may be outside of the spectral range of the camera 107. As such, the signal to noise ratio or the contrast ratio of camera 107 may be improved due to a lack of ambient noise being present in camera 107, or associated with HMD 100, as an eye tracking system.

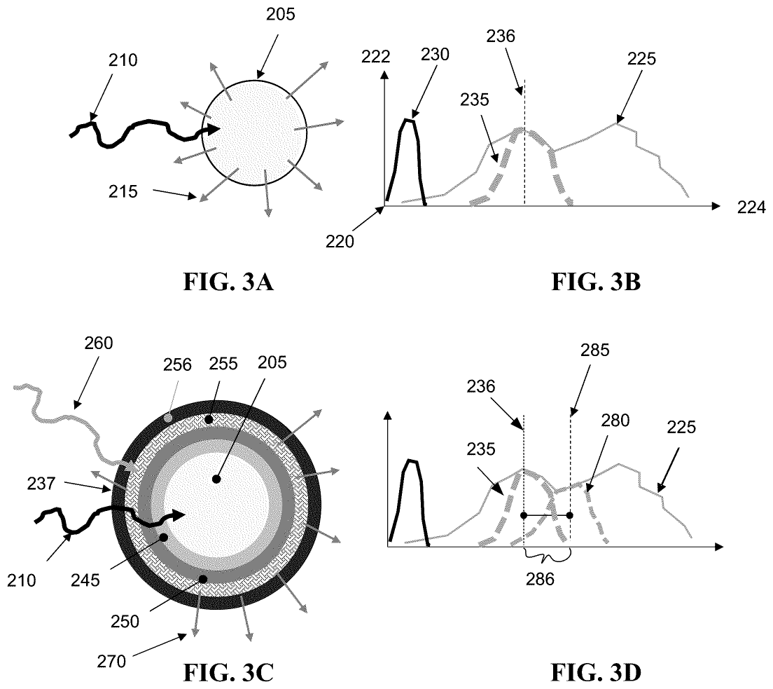

As disclosed, a fluorescent material may emit light within an emission waveband inherent to the material when excited by energy in the form of an electrical field, magnetic field, or light with a wavelength that is the material's absorption band. If the set of molecules in the material are arranged in a physical size that is resonant with a set of wavelengths in its emission band, then instead of emitting light across its entire emission band, the sized material may emit only in the band in which matches the size resonances. This class of sized or structured fluorescent material may be called fluorescent quantum dot (e.g., f-dot 205 in FIG. 3A). By sizing the f-dots 205, fluorescence waveband may be controlled so that f-dot 205 may emit with the emission waveband being centered about the mean f-dot size and its waveband emission distribution being a combination of f-dot size distribution coupled with an emission distribution (but sometimes much narrower than the material's overall distribution). F-dot 205 may be arranged in a shape of a sphere so that its resonance (and thus emission) is a Lambertian source when suitably energized. In many cases, such as when f-dot 205 is composed of an inorganic material, f-dot 205 is conformally coated with a monolayer protective layer to protect it from OH⁻, as this naturally occurring ion may quench (e.g., stop or prevent) florescence. The capability to place f-dot 205 into conformal layers of transparent materials may allow the resonance to be controlled by something other than sizing of f-dot 205.

For additional perspective, conventionally, phosphor may be in the shape of nanocrystals or random shape in which it might not be resonant with any wavelength in any direction. The shape of the phosphor may be occupying a disk in which the plane of the disk (e.g., circular, or elliptical) is resonant to a wavelength while its thickness is not resonant to any wavelength. Additionally, the in-plane resonance might be within the band of the emission spectra (in which case it may emit some of its light in that portion of the natural fluorescent band for photons travelling in plane) or the resonance may be out of band for the emission spectra (in which case the emission may be emitted in random directions or not at all). As disclosed herein, f-dot may be designed so that the shape and size of the f-dot dictates the emission direction, the waveband selection, or the potential for emission at all.

A Fabry Perot thin film cavity (FPTFC) is a resonant structure that may be applied to a surface and may be composed of alternating high refractive index materials and low refractive index materials on any side of a thicker defect layer to form a resonant cavity for light traversing normal (e.g., approximately orthogonal) to the surface. There may be thin alternating layers (two minimum, sometimes three or four different types) that may be quarter wave stacks, while the thicker defect layer may be minimum of a half wave and may increase in half wave steps depending on waveband(s) desired response.

FPTFC may be composed of dielectrics and metallic oxides but may include linear X-optical materials where ‘X’ may be electro, magneto, thermo, acousto, or chemo activation energy (e.g., an activation field), among other things. For example, chemo may be a chemical arrangement that may undergo a change in chemical makeup upon activation, such as an ion/free radical release or ion/free radical take-up upon activation (e.g., oxidation or reduction or a reversible cycle, such as what happens in electrochromic reactions). The X-optical material may be applied to the half wave stack element(s) and may allow the FPTFC to be an active structure in which the waveband center or its spectrum width may be tunable. In an example scenario, a resonance filter may be composed of quarter wave layers separated by a half wave layer. The number of quarter wave layers may dictate the band rejection qualities while the half wave layer dictates the waveband. The half wave layer may be a single layer of the same material, while the quarter wave layers may be alternating materials in which each quarter wave layer is composed of a homogenous material a quarter wave thick (layer ‘A’) and which the next layer is a different material, also a quarter wave thick (layer ‘B’). Thus, for two materials composing the quarter wave layers (e.g., stack), one may have A-B as a composite layer, and this may be repeated multiple times to form the qualities of the resonance about a waveband dictated by the thickness and composition of the half wave layer. Additionally, the minimum thickness for resonance is quarter wave or half wave but in making a resonant stack, the ensemble response is what is desired and thus some or all of the layers are used to achieve this. The stack structure may be composed of multiple features, such as 1) one which dictates the qualities of the resonance; 2) another dictates its location in wavelength space.

The emission spectra of f-dot 205 may be tuned to emit across the range of its emission spectrum by adjusting the apparent resonance of the FPTFC control structure(s). This may be performed by structuring f-dot 205 appropriately with resonances across the desired range and at the desired spectral bands (e.g., spectral radiance distribution 280 of FIG. 3D) and then activating various resonance within f-dot 205 using the control structure built into it and the appropriate activation energy to activate that set of resonances. The activation energy of light is discussed herein, but other forms of energy are contemplated for activating the stack structures that define FPTFC (FPTFC stack).

FIG. 3A-FIG. 3D illustrates an exemplary tunable f-dot. A Fabry Perot thin film cavity (FPTFC) may be applied to f-dot 205 using atomic layer deposition (ALD) methods with a monolayer being applied to f-dot 205 as per possible reasons as disclosed herein (e.g., hydroxyl protection). F-dot 205 may be excited by wave 210 at wavelength λ1. Excitation wave 210 may have spectral radiance distribution 230 in graph 220 of FIG. 3B.

In response to wave 210 there may be f-dot spectral radiance 215 (e.g., fluorescence), which may be at wavelength λ2. F-dot spectral radiance 215 may be at wavelength λ2 due to the size (e.g., volume) of standard f-dot 205 in combination with excitation by wave 210. The spectral response (e.g., spectral radiance distribution 235) is shown in graph 220. Graph 220 is a spectral emission graph composed of irradiance response (axis 222) versus spectral radiance distribution (axis 224). Spectral irradiance response curve 225 is an example spectral radiance response of the material response of standard f-dot spectral radiance 215 to wave 210.

Spectral radiance distribution 235 is an example distribution as a function of an underlying natural material response of f-dot 205 in correspondence with the size of f-dot 205. F-dot 205 at its size has a natural resonance indicated by line 236. Line 236 is an example center response for f-dot 205 and which is a natural resonance between the size of f-dot 205 and material's spectral irradiance response curve 225.

FIG. 3C illustrates an exemplary t-f-dot 237. T-f-dot 237 may include f-dot 205 (e.g., a core of t-f-dot 237) with one or more coatings (e.g., FPTFC), such as shell 245, shell 250, shell 255, or shell 256. It is contemplated that a coating may no encompass all (e.g., only half) of the previous inner core or coating.

As disclosed, f-dot 205 may be sized and composed of material to produce spectral radiance distribution 235 of FIG. 3B upon excitation by wave 210, assuming other coating layers (e.g., shell 245, shell 250, shell 255, or shell 256) are not activated by wave 210. This example is for simplicity, and it is contemplated that there may be complex impedance presented by the collection of shells which may affect the spectral radiance distribution 235 of f-dot 205 as shown in FIG. 3C.

Shell 245, shell 250, shell 255, or shell 256 are layers that may be passive or active. As shown, shell 245, shell 250, shell 255, or shell 256 are respectively the inner most layer surrounding f-dot 205 (shell 245) to the outer most layer surrounding f-dot 205 (shell 256). A passive layer may not be activated by a separate energy source. An active layer may be activated by a separate energy source (e.g., wave 210 or wave 260) and that source may modify some aspect of the complex impedance of a shell. The complex impedance may be composed of the complex permittivity or the complex permeability. Each of these material's characteristic aspect may be activated by energy carriers such as electrical/magnetic/phonon/chemical energy gradients (e.g., wave 210 or wave 260).

In an example, when shell 255 is activated based on the energy within wave 260 (e.g., at wavelength λ3) in addition to the energy within wave 210 (e.g., at wavelength λ1), the emission spectra of t-f-dot 237 may be changed. F-dot 205 may experience a different complex impedance moving the resonance to a different portion of the material's spectral irradiance response curve 225, as shown in FIG. 3D. FIG. 3D is an exemplary spectral emission graph composed of irradiance response (axis 222) versus spectra distribution (axis 224) that includes the spectral shift 86A. Shift 286 indicates an exemplary change from spectral radiance distribution 235 to spectral radiance distribution 280 upon activation (e.g., excitation) by wave 260. Spectral radiance distribution 280 has an exemplary center response as shown by line 285. The new spectral radiance 270 of FIG. 3C imposed by the adjustment in size of t-f-dot 237 by wave 260 on shell 255, activates a different portion (e.g., spectral radiance distribution 280 instead of spectral radiance distribution 235) of the material's spectral irradiance response curve 225 of FIG. 3D. The new spectral radiance 270 is an exemplary emission energy beam at wavelength λ4 caused by the action of wave 260 onto shell 255 while undergoing fluorescence of f-dot 205 by the actions of wave 210.

For additional perspective, the ‘size’ of f-dot 237 may be associated with size as seen by the optical field. The optical field may react to the permittivity of the volume that it enters, and the size of this volume may depend on the resonance of the surrounding materials so that the physical volume of the core of f-dot 237 might appear to be larger or smaller depending on how the surrounding layers resonate with this field. In the case of a tunable f-dot, a layer with the stack can be adjusted so that its permittivity is changed, and the stack's resonance is altered so the ensemble's volume is no longer in resonance with the optical field in which case f-dot 237 may be rendered invisible with the optical field (e.g., the optical field will not interact with it). Or alternatively, the field only reacts to f-dot 237 when the permittivity of the control layer has been affected. Gray scale alterations (instead of on/off type examples) of the f-dot's interaction are also contemplated.

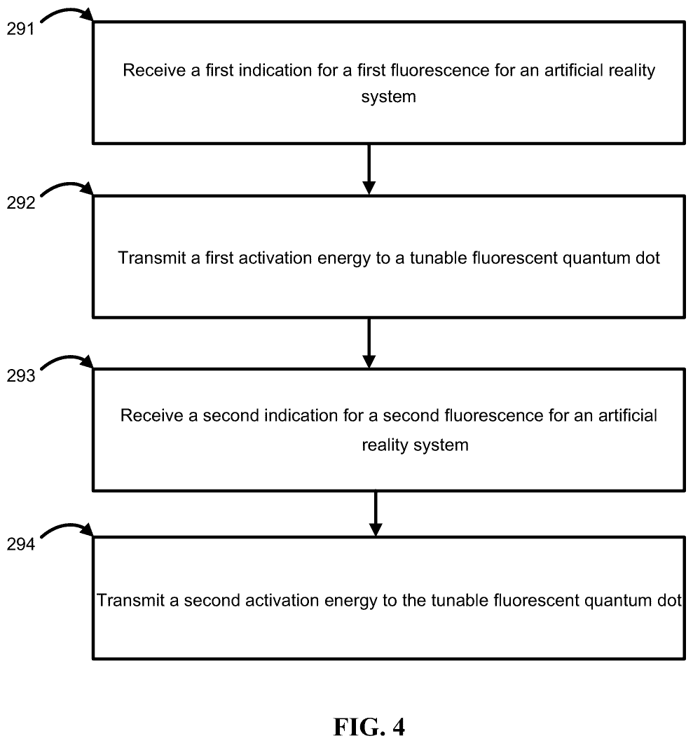

FIG. 4 illustrates an exemplary method for t-f-dot. At block 290, receive a first indication of a first fluorescence for a device (e.g., HMD 100). The HMD 100 may use the first fluorescence for eye tracking or other systems. At block 291, based on the first indication, transmit a first activation energy to a tunable fluorescent quantum dot 237, which causes the first fluorescence (e.g., a spectral radiance), which may or may not be visible to humans. At block 292, receive a second indication of a second fluorescence for HMD 100. The HMD 100 may use the second fluorescence for displaying information or other systems. At block 293, based on the second indication, transmit a second activation energy to a tunable fluorescent quantum dot 237, which causes the second fluorescence, which may or may not be visible to humans. The first activation energy and the second activation energy may be transmitted at the same time.

The tuning that may occur by using different waves may help create a dense color emission display using a remote tunable fluorescent quantum dot (t-f-dot) as an illumination for uses in artificial reality or other systems, while still permitting eye tracking functionality. Remote phosphor systems are ones that may be physically separated from its pump source. For example, the remote phosphor is located in or at the end of a waveguide. The source that activates the phosphor is located on at the input of the fiber or waveguide. In the case of a tunable fluorescent quantum dot, the tunable control signal/wavelength (e.g., may be separate from the wavelength on which the quantum dot acts on) may also be spatially separated from where the fluorescent quantum dot is located.

As disclosed, one or more layers in the t-f-dot 237 may be activated by an energy source (e.g., optically, electric fields, magnetic fields, plasmonic, exitonic, thermal, or chemical). The activation energy may cause the t-f-dot resonance to shift due to the increase or decrease of resonances that the emission from the t-f-dot 237 may experience. This increase or decrease in resonance may shift the emission wavelength towards the red or towards the blue of the fluorescence of the t-f-dot 237 and the t-f-dot 237 may emit depending on what the activation energy does to the control layers. The control features in the coatings may require the presence of one or more activation energy so that the timing between the energy beams (e.g., one or more of wave 260) may activate a control layer (e.g., shell 255) and allow the t-f-dot 237 to experience different resonances (e.g., higher, or lower resonances). Again, the control layer in conjunction with the activation energy may result in a change in the complex impedance that the emission wavelength experiences resulting in a change in the resonant response (e.g., spectral radiance) of the t-f-dot 237 (equivalent to changing is apparent size).

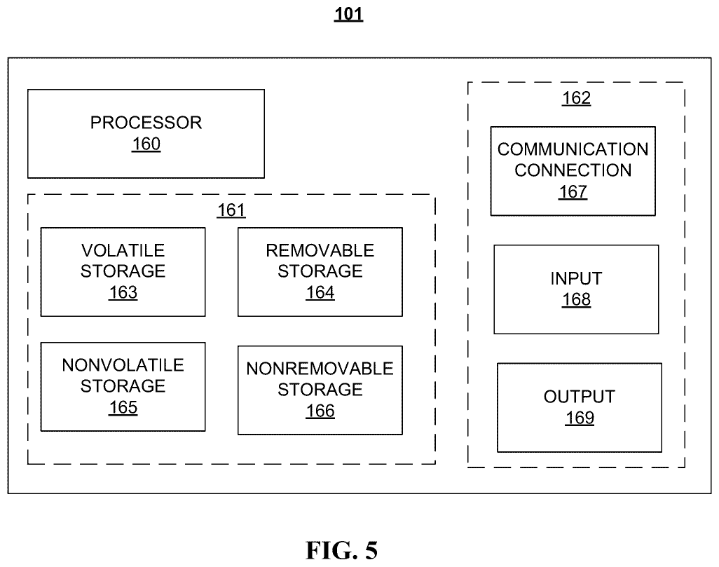

FIG. 5 is an exemplary block diagram of a device, such as HMD 100 or another device 101. In an example, HMD 100 may include hardware or a combination of hardware and software. The functionality to facilitate telecommunications via a telecommunications network may reside in one or combination of devices. A device may represent or perform functionality of one or more devices, such as a component or various components of a cellular broadcast system wireless network, a processor, a server, a gateway, a node, a gaming device, or the like, or any appropriate combination thereof. It is emphasized that the block diagram depicted in FIG. 5 is exemplary and not intended to imply a limitation to a specific implementation or configuration. Thus, HMD 100, for example, may be implemented in a single device or multiple devices (e.g., single server or multiple servers, single gateway or multiple gateways, or single controller or multiple controllers). Multiple network entities may be distributed or centrally located. Multiple network entities may communicate wirelessly, via hardwire, or any appropriate combination thereof.

HMD 100 or another device may comprise a processor 160 or a memory 161, in which the memory may be coupled with processor 160. Memory 161 may contain executable instructions that, when executed by processor 160, cause processor 160 to effectuate operations associated with t-f-dot system, or other subject matter disclosed herein.

In addition to processor 160 and memory 161, HMD 100, or another device may include an input/output system 162. Processor 160, memory 161, or input/output system 162 may be coupled together (coupling not shown in FIG. 5) to allow communications between them. Each portion of HMD 100 or another device 101 may include circuitry for performing functions associated with each respective portion. Thus, each portion may include hardware, or a combination of hardware and software. Input/output system 162 may be capable of receiving or providing information from or to a communications device or other network entities configured for telecommunications. For example, input/output system 162 may include a wireless communication (e.g., Wi-Fi, Bluetooth, or 5G) card. Input/output system 162 may be capable of receiving or sending video information, audio information, control information, image information, data, or any combination thereof. Input/output system 162 may be capable of transferring information with HMD 100 or another device 101. In various configurations, input/output system 162 may receive or provide information via any appropriate means, such as, for example, optical means (e.g., infrared), electromagnetic means (e.g., radio frequency (RF), Wi-Fi, Bluetooth), acoustic means (e.g., speaker, microphone, ultrasonic receiver, ultrasonic transmitter), or a combination thereof. In an example configuration, input/output system 162 may comprise a Wi-Fi finder, a two-way GPS chipset or equivalent, or the like, or a combination thereof.

Input/output system 162 of HMD 100 or another device 101 also may include a communication connection 167 that allows HMD 100 or another device 101 to communicate with other devices, network entities, or the like. Communication connection 167 may comprise communication media. Communication media typically embody computer-readable instructions, data structures, program modules or other data in a modulated data signal such as a carrier wave or other transport mechanism and includes any information delivery media. By way of example, and not limitation, communication media may include wired media such as a wired network or direct-wired connection, or wireless media such as acoustic, RF, infrared, or other wireless media. The term computer-readable media as used herein includes both storage media and communication media. Input/output system 162 also may include an input device 168 such as keyboard, mouse, pen, voice input device, or touch input device. Input/output system 162 may also include an output device 169, such as a display, speakers, or a printer.

Processor 160 may be capable of performing functions associated with telecommunications, such as functions for processing broadcast messages, as described herein. For example, processor 160 may be capable of, in conjunction with any other portion of HMD 100 or another device 101, determining a type of broadcast message and acting according to the broadcast message type or content, as described herein.

Memory 161 of HMD 100 or another device 101 may comprise a storage medium having a concrete, tangible, physical structure. As is known, a signal does not have a concrete, tangible, physical structure. Memory 161, as well as any computer-readable storage medium described herein, is not to be construed as a signal. Memory 161, as well as any computer-readable storage medium described herein, is not to be construed as a transient signal. Memory 161, as well as any computer-readable storage medium described herein, is not to be construed as a propagating signal. Memory 161, as well as any computer-readable storage medium described herein, is to be construed as an article of manufacture.

Herein, a computer-readable storage medium or media may include one or more semiconductor-based or other integrated circuits (ICs) (such, as for example, field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable storage medium may be volatile, non-volatile, or a combination of volatile and non-volatile, where appropriate.

While the disclosed systems have been described in connection with the various examples of the various figures, it is to be understood that other similar implementations may be used or modifications and additions may be made to the described examples of a t-f-dot system, among other things as disclosed herein. For example, one skilled in the art will recognize that a t-f-dot system, among other things as disclosed herein in the instant application may apply to any environment, whether wired or wireless, and may be applied to any number of such devices connected via a communications network and interacting across the network. Therefore, the disclosed systems as described herein should not be limited to any single example, but rather should be construed in breadth and scope in accordance with the appended claims.

In describing preferred methods, systems, or apparatuses of the subject matter of the present disclosure—t-f-dot system—as illustrated in the Figures, specific terminology is employed for the sake of clarity. The claimed subject matter, however, is not intended to be limited to the specific terminology so selected.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value or to the other particular value. Similarly, when values are expressed as approximations, by use of the antecedent “about,” it will be understood that the particular value forms another embodiment. All ranges are inclusive and combinable. It is to be understood that the terminology used herein is for the purpose of describing particular aspects only and is not intended to be limiting.

This written description uses examples to enable any person skilled in the art to practice the claimed subject matter, including making and using any devices or systems and performing any incorporated methods. Other variations of the examples are contemplated herein. It is to be appreciated that certain features of the disclosed subject matter which are, for clarity, described herein in the context of separate embodiments, may also be provided in combination in a single embodiment. Conversely, various features of the disclosed subject matter that are, for brevity, described in the context of a single embodiment, may also be provided separately or in any sub-combination. Further, any reference to values stated in ranges includes each and every value within that range. Any documents cited herein are incorporated herein by reference in their entireties for any and all purposes.

The scope of this disclosure encompasses all changes, substitutions, variations, alterations, and modifications to the example embodiments described or illustrated herein that a person having ordinary skill in the art would comprehend. The scope of this disclosure is not limited to the examples described or illustrated herein. Moreover, although this disclosure describes and illustrates respective embodiments herein as including particular components, elements, feature, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

Methods, systems, and apparatuses, among other things, as described herein may provide for a tunable f-dot. A method, system, computer readable storage medium, or apparatus may provide for a tunable fluorophore, in which tunable fluorophore comprises a core, wherein the core comprises a fluorescent quantum dot (f-dot), phosphor, or a fluorescent nanocrystal of a first size, the core comprises a first material that is activated by a first activation energy; and a first coating layer, wherein the first coating layer substantially encompasses the core, the first coating layer comprises a second material that is activated by a second activation energy, wherein the first activation energy may be different from the second activation energy. The first activation energy may not activate the second material. The tunable fluorescent quantum dot may be incorporated within an artificial reality system and may be used for eye tracking or changing images on a display. The tunable fluorescent quantum dot may include a second coating layer, wherein the second coating layer substantially encompasses the core and the first coating layer, the second coating layer comprises a third material that is activated by a third activation energy, and wherein the third activation energy is different from the first activation energy and the second activation energy. The tunable fluorophore is incorporated within an electronic display. The first material may be activated to emit a first spectral radiance that is different from a second spectral radiance that is activated by the second activation energy. The first material may be activated to fluoresce based on the first activation energy. The first activation energy may include electrical energy, magnetic energy, phonon energy, or chemical energy of one or more wavelengths. The first activation energy may be light. The first activation energy may be a wavelength that is different from the second activation energy. All combinations in this paragraph and the following paragraph (including the removal or addition of steps) are contemplated in a manner that is consistent with the other portions of the detailed description.

A method, system, computer readable storage medium, or apparatus may provide for the use of a plurality of tunable fluorescent quantum dots. The plurality of tunable fluorescent quantum dots may include t-f-dots of different sizes which may have different spectral resonances based on the different sizes of the respective t-f-dots or different spectral resonances based on the different materials of the respective t-f-dots. The method, system, computer-readable storage medium, or apparatus may provide for transmitting a first activation energy to a tunable fluorescent quantum dot, the tunable fluorescent quantum dot comprises a core of a first size, the core comprises a first material that is activated by the first activation energy to a first fluorescence (e.g., a first color); receiving an indication (e.g., a communication) to change the tunable fluorescent quantum dot to a second fluorescence (e.g., a second color), wherein the first fluorescence is different than the second fluorescence; and based on the indication to change, transmitting a second activation energy to a first coating layer of the tunable fluorescent quantum dot, the second activation energy causing the second fluorescence. The first activation energy and the second activation energy may be transmitted during a same time interval. The first material may be activated to emit a third spectral radiance (e.g., to fluoresce) based on a third activation energy. The second activation energy may include chemical particles. The second material may include a thin film cavity. The first activation energy may not activate the second material or may below a threshold of activation so that the activation of the second material is minimal and may not be perceptible or used by a system. All combinations in this paragraph (including the removal or addition of steps) are contemplated in a manner that is consistent with the other portions of the detailed description.

The language used in the specification has been principally selected for readability and instructional purposes, and it may not have been selected to delineate or circumscribe the inventive subject matter. It is therefore intended that the scope of the patent rights be limited not by this detailed description, but rather by any claims that issue on an application based hereon. Accordingly, the disclosure of the examples is intended to be illustrative, but not limiting, of the scope of the patent rights, which is set forth in the following claims.

What is claimed:

1. A tunable fluorescent quantum dot comprising:
a core comprising a fluorescent quantum dot having a first size, wherein the core comprises a first material that is activated by a first activation energy; and
a first coating layer substantially encompassing the core, wherein the first coating layer comprises a second material that is activated by a second activation energy, wherein the first activation energy is different from the second activation energy.

2. The tunable fluorescent quantum dot of claim 1, wherein the first activation energy does not activate the second material.

3. The tunable fluorescent quantum dot of claim 1, wherein the tunable fluorescent quantum dot is incorporated within an artificial reality system.

4. The tunable fluorescent quantum dot of claim 1, further comprising:
a second coating layer substantially encompassing the core and the first coating layer,
wherein the second coating layer comprises a third material that is activated by a third activation energy, and
wherein the third activation energy is different from the first activation energy and the second activation energy.

5. The tunable fluorescent quantum dot of claim 1, wherein the first material is activated to emit a first spectral radiance that is different from a second spectral radiance that is activated by the second activation energy.

6. The tunable fluorescent quantum dot of claim 1, wherein the first material is activated to emit a first spectral radiance based on the first activation energy.

7. The tunable fluorescent quantum dot of claim 1, wherein the first activation energy comprises electrical energy or magnetic energy.

8. The tunable fluorescent quantum dot of claim 1, wherein the second activation energy comprises phonon energy or chemical energy.

9. The tunable fluorescent quantum dot of claim 1, wherein the first activation energy comprises a first wavelength that is different than the second activation energy which comprises a second wavelength.

10. An apparatus comprising:
one or more processors; and
at least one memory storing instructions, that when executed by the one or more processors, cause the apparatus to:
transmit a first activation energy to a tunable fluorescent quantum dot, the tunable fluorescent quantum dot comprises a core comprising a fluorescent quantum dot having a first size, wherein the core comprises a first material that is activated by the first activation energy to a first spectral radiance;
receive an indication to change the tunable fluorescent quantum dot to a second spectral radiance, wherein the first spectral radiance is different than the second spectral radiance; and
transmit, based on the indication to change, a second activation energy to a first coating layer of the tunable fluorescent quantum dot, the first coating layer comprising a second material, wherein the second activation energy causes the second spectral radiance.

11. The apparatus of claim 10, wherein the indication to change the tunable fluorescent quantum dot is from a component of an artificial reality system.

12. The apparatus of claim 10, wherein the first spectral radiance or the second spectral radiance is used with an eye tracking system of an artificial reality system.

13. The apparatus of claim 10, wherein the first spectral radiance or the second spectral radiance to facilitate display by an artificial reality system.

14. The apparatus of claim 10, wherein the first activation energy comprises magnetic energy.

15. The apparatus of claim 10, wherein the second activation energy comprises phonon energy.

16. A method comprising:
transmitting a first activation energy to a tunable fluorescent quantum dot, the tunable fluorescent quantum dot comprises a core comprising a fluorescent quantum dot having a first size, the core comprises a first material that is activated by the first activation energy to a first spectral radiance;
receiving an indication to change the tunable fluorescent quantum dot to a second spectral radiance, wherein the first spectral radiance is different than the second spectral radiance; and
transmitting, based on the indication to change, a second activation energy to a first coating layer of the tunable fluorescent quantum dot, the first coating layer comprising a second material, wherein the second activation energy causes the second spectral radiance.

17. The method of claim 16, the first spectral radiance or the second spectral radiance is used with an eye tracking system of an artificial reality system.

18. The method of claim 16, wherein the first spectral radiance or the second spectral radiance to facilitate display by an artificial reality system.

19. The method of claim 16, wherein the first activation energy comprises electrical energy.

20. The method of claim 16, wherein the second activation energy comprises chemical particles.
